(19) United States
(12) Patent Application Publication
(10) Pub. No.: US 2026/0182396 A1
(43) Pub. Date: Jun. 25, 2026

(54) METHOD OF MANUFACTURING SEMICONDUCTOR DEVICES AND CORRESPONDING SEMICONDUCTOR DEVICE

(71) Applicant: STMicroelectronics International N.V., Geneva (CH)

(72) Inventors: Alessandro MELLINA GOTTARDO, Milano (IT); Federico LEONE, Lodi (IT)

(73) Assignee: STMicroelectronics International N.V., Geneva (CH)

(21) Appl. No.: 19/425,608

(22) Filed: Dec. 18, 2025

(30) Foreign Application Priority Data
Dec. 24, 2024 (IT) 102024000029889

(51) Int. Cl. H10W 70/40; H10W 70/04; H10W 74/01; H10W 74/10; H10W 90/00

(52) U.S. Cl. CPC H10W 70/435; H10W 70/04; H10W 70/411; H10W 74/016; H10W 74/114; H10W 90/756

(57) ABSTRACT

A substrate includes a die pad and an array of electrically conductive leads around the die pad. A semiconductor die is arranged on the die pad. Selected portions of a surface of the substrate have a roughened surface finishing. An electrically insulating encapsulation is molded onto the semiconductor die arranged onto the die pad. The electrically insulating encapsulation contacts the roughened surface finishing. The roughened surface finishing counters delamination of the electrically insulating encapsulation from the surface of the substrate. The roughened surface finishing is formed at the selected portions of the surface by: forming an adhesion promoter finishing layer over the surface of the substrate, and applying laser beam energy to said selected portions of the surface of the substrate.

### PRIORITY CLAIM

This application claims the priority benefit of Italian Application for Patent No. 102024000029889 filed on Dec. 24, 2024, the content of which is hereby incorporated by reference in its entirety to the maximum extent allowable by law.

### TECHNICAL FIELD

The description relates to semiconductor devices.

One or more embodiments can be applied to semiconductor devices including integrated circuits (ICs), for instance.

### BACKGROUND

Current integrated circuit (IC) semiconductor devices, such as quad flat no-lead (QFN) or quad flat package (QFP), comprise a plastic package embedding a semiconductor die arranged on a substrate such as a leadframe.

The package is provided by molding an electrically insulating molding compound (an epoxy resin, for instance) onto the substrate having the semiconductor die attached thereon.

The plastic package protects the semiconductor die from humidity and/or contaminants that could damage the semiconductor die, possibly causing reliability issues (die corrosion or detachment, for instance) and, in worst cases, failure of the device. Inadequate adhesion between the molding compound and the substrate (of metallic material in the case of a leadframe) may result in delamination of the package from the substrate. In certain cases, the degree of delamination is such that humidity and contaminants can penetrate the package and reach the semiconductor die (or dice) embedded therein.

Reference is made to United States Patent Application Publication Nos. 2020/0402895 A1, 2021/0335686 A1, 2018/0082921 A1, 2010/0323099 A1, and 2012/0118753 A1, as well as P. Brooks et al., “Novel approach for a non-etching adhesion promoter for the next generation of IC substrates,” 2007 International Microsystems, Packaging, Assembly and Circuits Technology, all of which are incorporated herein by reference, which provide background information in the related technological area.

There is a need in the art to overcome the drawbacks discussed in the foregoing.

### SUMMARY

One or more embodiments relate to a method.

One or more embodiments relate to a corresponding (integrated circuit) semiconductor device.

Solutions as described comprise forming a roughened surface finishing at selected portions of the surface of a substrate for semiconductor device (a leadframe, for instance). The roughened surface finishing enhances adhesion between the encapsulation and the substrate, reducing the risk of delamination.

In solutions as described herein, a roughened surface finishing is formed by forming an adhesion promoter surface layer and by laser-roughening selected portions of the substrate.

In solutions as described herein, the adhesion promoter surface layer may be formed subsequently to the laser-roughening step.

Solutions as described herein may comprise applying laser beam energy to selected portions of the substrate having (already) formed thereon an adhesion promoter surface layer.

In solutions as described herein, a roughened surface finishing may be formed at selected portions of the leads and/or at selected portions of a die pad.

### BRIEF DESCRIPTION OF THE DRAWINGS

One or more embodiments will now be described, by way of example only, with reference to the annexed figures, wherein:

FIG. 1 is a cross-sectional view of a semiconductor device;

FIGS. 2 and 3 are an enlarged view corresponding to the portions of FIG. 1 indicated by the arrow II and III, respectively, illustrating possible problems in a device as illustrated in FIG. 1,

FIGS. 4 and 5 (wherein FIG. 5 is an enlarged view of the portion of FIG. 4 indicated by the arrow V) are plan views illustrative of a substrate;

FIGS. 6A and 6B are block diagrams illustrative of sequences of processing steps, and

FIGS. 7 and 8 are cross-sectional views illustrative of details of a semiconductor device obtainable via processing steps.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The headings/references used herein are provided merely for convenience and hence do not define the extent of protection or the scope of the embodiments.

For simplicity and ease of explanation, throughout this description, and unless the context indicates otherwise, like parts or elements are indicated in the various figures with like reference signs, and a corresponding description will not be repeated for each and every figure.

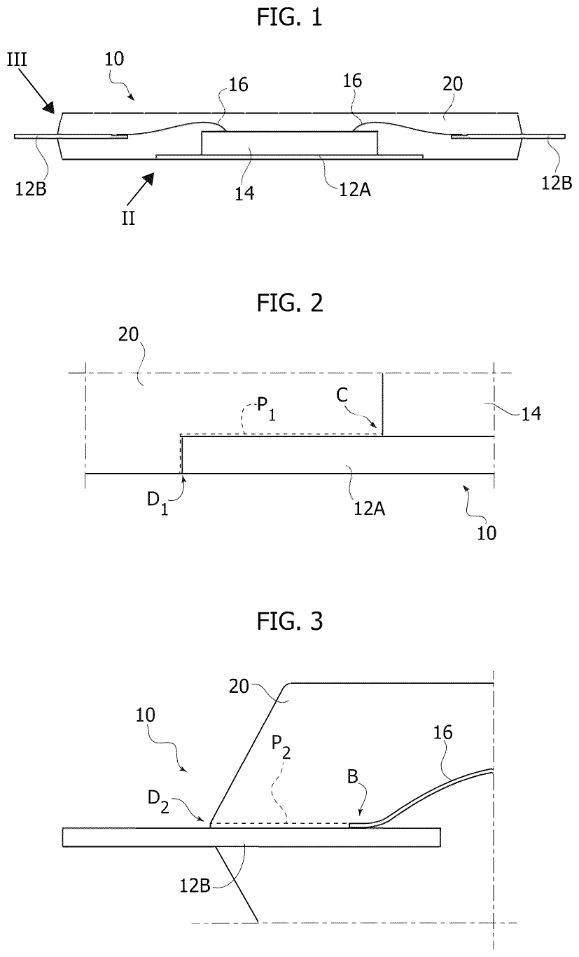

FIG. 1 illustrates a cross-sectional view of (integrated circuit (IC)) semiconductor device 10.

The exemplary device 10 illustrated in FIG. 1 comprises: a semiconductor (Si, SiC or GaN, for instance) die or chip 14 (the terms chip/s and die/dice are herein regarded as synonymous) mounted on a top/front surface of a die pad 12A in a leadframe; and an array of leads 12B around the die pad 12A having the die (or dice) 14 mounted thereon.

As illustrated herein by way of example, an (integrated circuit (IC)) semiconductor device such as the device 10 comprises, in addition to a substrate/leadframe (that is the die pad 12A plus the leads 12B) having one or more semiconductor chips or dice 14 arranged thereon:
electrically conductive formations such as wires 16, for instance, that electrically couple the semiconductor die 14 to leads (outer pads) 12B in the substrate; and an electrically insulating encapsulation 20 of molding material (an epoxy resin, for instance) molded on the assembly to form the plastic body of the device 10.

The designation “leadframe” (or “lead frame”) is currently used (see, for instance the USPC Consolidated Glossary of the United States Patent and Trademark Office) to indicate a metal frame that provides support for an integrated circuit chip or die as well as electrical leads to interconnect the integrated circuit in the die or chip to other electrical components or contacts.

Essentially, a leadframe comprises an array of electrically-conductive formations (or leads, 12B) that from an outline location extend inwardly in the direction of a semiconductor chip or die 14 thus forming an array of electrically-conductive formations from a die pad (such as the die pad 12A illustrated in FIG. 1) configured to have at least one (IC) semiconductor chip or die attached thereon. This may be via conventional means such as a die attach adhesive (a die attach film or DAF, for instance, not illustrated in the figures for simplicity).

A device 10 as exemplified herein is of a type that is oftentimes referred to as quad flat package (QFP) where the die pad 12A may be provided with a “downset” from the leads 12B.

It will be appreciated that the details of the structure of a device 10 as discussed herein are merely exemplary and should not be construed in a limiting sense; in fact, solutions as described herein may be applied also to other types of leadframe such as quad flat no-lead (QFN) leadframes.

As mentioned, an electrically insulating molding compound is molded onto the devices subsequent to providing the desired electrical coupling between the die 14 and the leadframe. The package thus formed protects the semiconductor die 14 from humidity and/or contaminants that could cause failure of the device 10.

However, it is observed that reliability of the package may be negatively affected by inadequate adhesion between the molding compound 20 of the encapsulation and the metallic material (copper, for instance) of the leadframe (die pad 12A and leads 12B).

FIGS. 2 and 3 are enlarged views of the portions of FIG. 1 indicated by the arrows II and III, respectively, illustrative of possible delamination related issues that may arise in a semiconductor device 10 as illustrated in FIG. 1.

With reference to FIG. 2, delamination of the package is more likely to start at a point D1 of the interface between the metallic material of the die pad 12A and the molding compound 20 of the encapsulation that is exposed at the (bottom/top) surface of the device 10. As illustrated, delamination may progress along a delamination path P1 and eventually reach the semiconductor die 14 arranged at the die pad 12A (at the point indicated with the reference C in FIG. 2).

Similarly, now referring to FIG. 3, delamination may start at point D2 at the interface between the metallic material of a lead 12B and the molding compound 20 of the encapsulation that is exposed at the (side) surface of the device 10. Delamination may progress along the delamination path P2 and eventually reach the portion of the lead 12B providing a landing point B to an electrically conductive wire 16. Delamination of the package 20 at the landing point B of the lead mechanically stresses the wires, possibly causing the wire 16 to detach from the lead 12B.

According to one approach, an adhesion promoter layer (a non-etching adhesion promote (NEAP) layer) may be formed at the surface of the substrate in order to enhance adhesion between the molding compound and the substrate. However, there are cases where a NEAP layer does not give satisfactory results in terms of enhanced adhesion, as it is observed that NEAP can partially be affected by moisture absorption, with negative consequences on the adhesion.

According to another approach, the surface may be chemically roughened (for instance by exposing the surface of the leadframe to dedicated chemical baths) in order to increase mechanical interlocking of the resin with the leadframe. Such treatment, however, increases the cost of leadframes, making the manufacturing process cost ineffective. Moreover, leadframe roughening alone does not overcome the issues related to the delamination of the package from the leadframe.

Solutions as described comprise forming a roughened surface finishing at selected portions of the surface of a substrate for semiconductor device (a leadframe, for instance). The roughened surface finishing enhances adhesion between the encapsulation and the substrate, reducing the risk of delamination.

In solutions as described herein, a roughened surface finishing is formed by forming an adhesion promoter surface layer and by laser-roughening selected portions of the substrate.

In solutions as described herein, the adhesion promoter surface layer may be formed subsequently to the laser-roughening step.

Solutions as described herein may comprise applying laser beam energy to selected portions of the substrate having (already) formed thereon an adhesion promoter surface layer.

In solutions as described herein, a roughened surface finishing may be formed at selected portions of the leads and/or at selected portions of a die pad.

In current manufacturing processes of semiconductor devices, plural devices are manufactured concurrently to be separated into single individual device in a final singulation step. For simplicity and ease of explanation, the following description will refer to manufacturing a single device.

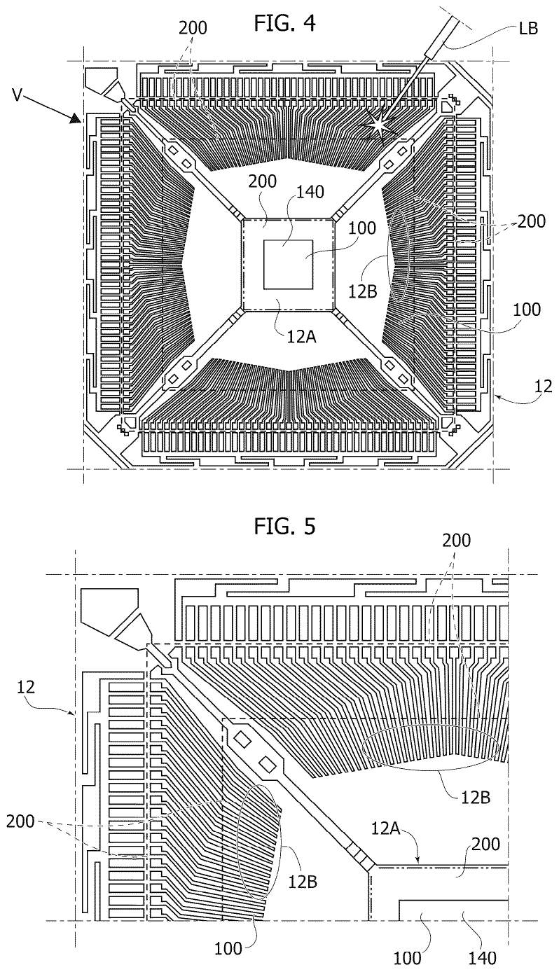

FIGS. 4 and 5 (wherein FIG. 5 is an enlarged view of the portion of FIG. 4 indicated by the arrow V) are illustrative of processing steps according to embodiments of the present description.

FIG. 4 is illustrative of a substrate 12 (a leadframe, for instance) comprising a die pad 12A and arrays of electrically conductive leads 12B around the die pad 12A. As illustrated, the die pad 12A comprises a die mounting portion 140 configured to have the semiconductor die 14 attached thereto.

According to embodiments of the present description, selected portions of the top/front surface of the substrate 12 are subjected to a combined treatment to enhance the adhesion of the substrate 12 with the encapsulation subsequently molded onto the substrate 12. More in detail, such a combined treatment comprises: forming an adhesion promoter surface layer 100 such as a non-etching adhesion promoter (NEAP) surface finishing, for instance; and a laser-roughening treatment.

As illustrated in FIGS. 4 and 5, the adhesion promoter surface layer 100 may be formed over the (whole) surface of the substrate 12.

Forming such a surface layer 100 may be considered per se known in the art and will not be further described.

Selected portions of the surface of the substrate 12 are also subjected to a laser roughening process. Laser roughening may be performed on the substrate 12 either prior to or after forming the surface layer 100.

A laser roughening process comprises applying laser beam energy LB to a surface to partially etch/ablate material therefrom; a roughened surface is formed in response to the partial etching/ablation of the material of the surface.

It is noted that by roughened surface it is meant a surface that is made rough (via laser-roughening, for instance).

Laser roughening may comprise etching/ablating material according to a lasering pattern. A possible lasering pattern comprises a grid-like pattern comprising lines with a pitch ranging from few microns to millimeters. A line width (that is, the width of the area affected by the laser) may be of the order of 20 microns.

The parameters described above are merely exemplary and must not be construed in a limiting sense of the embodiments.

A roughened surface having an arithmetic roughness (as measured via optical measurement) between 250 and 500 nanometers (nm), preferably between 350 nm and 500 nm may be formed.

The combined treatment results in roughened surface finishing 200 formed at selected portions of the surface of the substrate 12.

Said otherwise, forming the roughened surface finishing comprises: forming an adhesion promoter finishing layer 100 over the surface of the substrate 12; and applying laser beam energy LB to selected portions of the surface of the substrate 12 to form a roughened surface at these selected portions of the surface of the substrate 12.

As illustrated in FIGS. 4 and 5, the roughened surface finishing 200 may be formed at a portion of the leads 12B. The portion of the leads 12B having a roughened surface finishing is illustrated in FIGS. 4 and 5 as the region defined by the two dashed lines indicated with the reference 200. Advantageously, the roughened surface finishing 200 may be formed at the distal portion of the leads 12B in order not to affect the wire bonding process, wherein electrically conductive wires (extending between a semiconductor die 14 arranged at the die pad 12A and the leads 12B) are bonded at the proximal portion of the leads 12B.

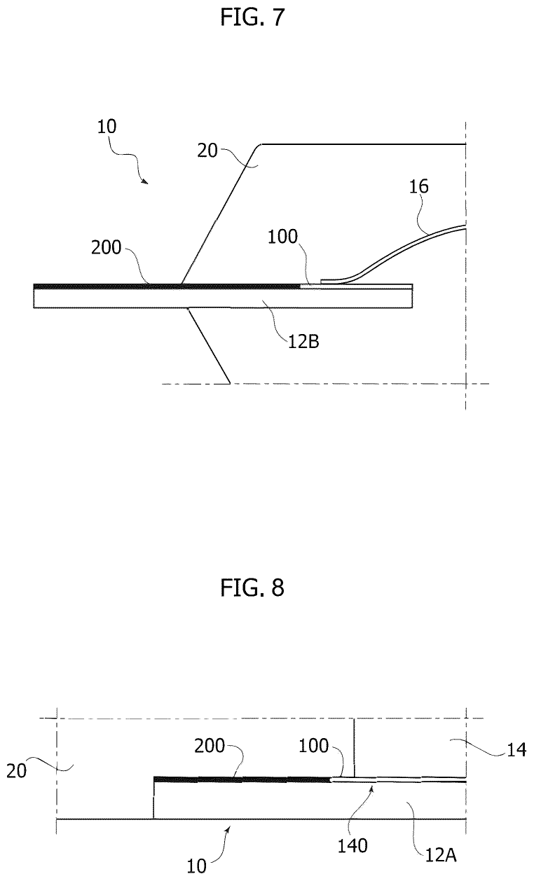

That is, the electrically conductive leads 12B in the array of electrically conductive leads 12B comprise a proximal lead portion and a distal lead portion. A roughened surface finishing 200 may be formed at the distal lead portion of the electrically conductive leads 12B in the array of electrically conductive leads 12B, and electrically conductive formations (for instance, wires 16 visible in FIG. 7, for instance) are provided from a semiconductor die arranged at a surface of the die pad 12A and the proximal lead portion of selected leads 12B to provide electrical coupling therebetween.

A roughened surface finishing may be formed at selected portions of the surface of the die pad 12A. As illustrated in FIG. 4, the surface of the die pad 12A comprises a die mounting region 140 that is configured to have a semiconductor die attached thereto. A roughened surface finishing 200 may be formed at portions of the surface of the die pad 12A neighboring the die mounting portion 140.

In the exemplary embodiment illustrated in FIG. 4, the die mounting portion 140 is located at the center of the die pad 12A and a roughened surface finishing may be formed at a peripheral portion around the die mounting portion 140.

In one or more embodiments, a roughened surface finishing 200 may be formed also at the die mounting portion 140 in cases where such a roughened surface finishing 200 is compatible with the die-attach material used.

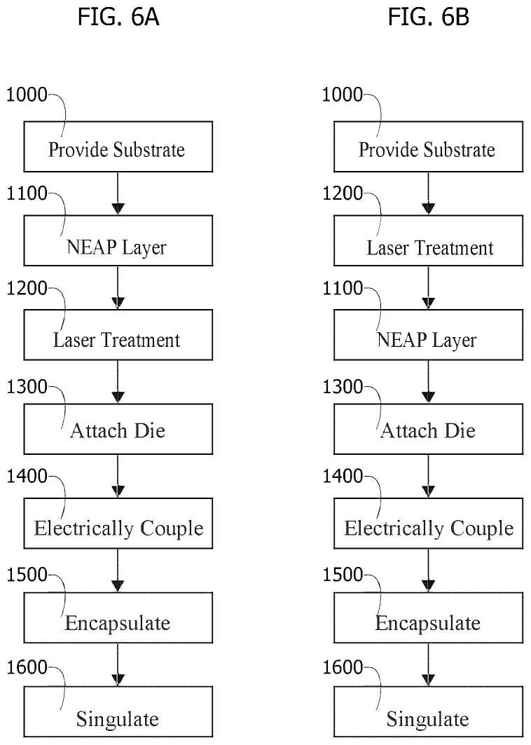

FIGS. 6A and 6B are block diagrams illustrative of sequences of processing steps according to embodiment of the present description.

First, a substrate 12 (a leadframe, for instance) is provided in Step 1000. As known to those skilled in the art, a plurality of individual substrates/leadframes may be provided by providing a panel or reel comprising a plurality of substrates/leadframes held together via dam bars and tie bars, subsequently removed in a singulation step.

The block referenced with reference Step 1100 in FIGS. 6A and 6B represents a processing step wherein an adhesion promoter surface layer 100, for example a NEAP layer, is formed at the surface of the substrate 12.

As mentioned, the adhesion promoter surface layer 100 may be formed over the whole surface of the substrate 12.

The block referenced with reference Step 1200 in FIGS. 6A and 6B represents a processing step comprising applying laser beam energy LB to selected portions of the surface of the substrate 12 to form therein a roughened surface.

As illustrated in FIG. 6A, the laser roughening step may be performed subsequently to the formation of an adhesion promoter surface layer 100. In this case, applying laser beam energy to selected portions of the substrate 12 having the adhesion promoter surface layer 100 may result in the adhesion promoter surface layer 100 being partially removed (etched/ablated).

With reference to the sequence of steps illustrated in FIG. 6B, in particularly advantageous embodiments, the adhesion promoter surface finishing may be formed at the (whole) surface of the substrate 12 subsequently to a laser roughening step. That is, the adhesion promoter surface layer 100 is formed at the (whole) surface of substrate 12 having selected portions thereof laser roughened.

In both cases, a roughened surface finishing 200 is formed at selected portions of the surface of the substrate 12.

Subsequent steps in the sequences illustrated in FIGS. 6A and 6B comprise:
Step 1300—attaching (at least) one semiconductor die 14 at a die pad 12A in the substrate; this may be via conventional die attach material, such as a die attach film or glue, for instance;
Step 1400—providing electrical coupling between the semiconductor die 14 arranged at the die pad 12A and selected leads 12B in the array of electrically conductive leads 12B around the die pad 12A;
Step 1500—molding an electrically insulating encapsulation 20 onto the semiconductor die 14 arranged at the die pad 12A, and
Step 1600—singulating the panel/reel into a plurality of individual, finished, semiconductor devices 10.

FIGS. 7 and 8 are illustrative of details of a semiconductor device 10 obtainable via a method as described in the foregoing.

FIG. 7 is illustrative of a portion of a semiconductor device 10 (corresponding to the portion of semiconductor device illustrated in FIG. 3) processed according to embodiments of the present description.

As illustrated, a roughened surface finishing 200 may be formed at the distal portion (2 to 3 millimeters inward from the distal end of the leads 12B, for instance) of the electrically conductive leads 12B in the array of electrically conductive leads 12B. An adhesion promoter surface layer 100 is left at the proximal portion of the electrically conductive leads 12B.

Electrically conductive formations 16 (wires, for instance) are provided from the semiconductor die 14 arranged at the surface of the die pad 12A and the proximal lead portion having the adhesion promoter layer 100 formed thereon.

FIG. 8 is illustrative of a portion of a semiconductor device 10 (corresponding to the portion of semiconductor device illustrated in FIG. 2) processed according to embodiments of the present description. As illustrated a roughened surface finishing 200 may be formed at portions of the (top/front) surface of the die pad 12A neighboring the die mounting portion 140.

As illustrated in FIGS. 7 and 8, the electrically insulating encapsulation 20 contacts the roughened surface finishing 200 formed at selected portions the surface of the substrate 12. The roughened surface finishing 200 effectively counters delamination of the electrically insulating encapsulation 20 from the surface of the substrate 12.

In summary, a roughened surface finishing 200 is formed at selected portions of a surface of a substrate 12. The substrate 12 comprises a die pad 12A (configured to have a semiconductor die attached thereto) and an array of electrically conductive leads 12B around the die pad 12A.

Forming the roughened surface finishing 200 at selected portions of the surface of the substrate 12 comprises: forming an adhesion promoter finishing layer 100 over the surface of the substrate 12; and applying laser beam energy LB to the selected portions of the surface of the substrate 12 to form a roughened surface at the selected portions of the surface of the substrate 12.

A semiconductor die 14 is arranged onto the die pad 12A at the surface of the substrate 12 having the roughened surface finishing 200 formed at selected portions of the surface thereof.

An electrically insulating encapsulation 20 is molded onto the semiconductor die 14 arranged onto the die pad 12A. The electrically insulating encapsulation 20 contacts the roughened surface finishing 200 formed at selected portions of the surface of the substrate 12. The roughened surface finishing 200 counters delamination of the electrically insulating encapsulation (20) from the surface of the substrate 12.

Forming the roughened surface finishing 200 at the selected portions of the surface may comprise applying laser beam energy LB to the selected portions of the surface of the substrate 12 having the adhesion promoter finishing layer 100 formed thereon. The adhesion promoter finishing layer 100 is partially removed from the selected portions of the surface in response to the laser beam energy LB being applied thereto.

In one or more embodiments, a roughened surface finishing 200 is formed at distal lead portion of the electrically conductive leads 12B in the array of electrically conductive leads 12B. Electrically conductive formations 16 are provided from the semiconductor die 14 arranged at the surface of the die pad 12A and the proximal lead portion of selected leads 12B in the array of electrically conductive leads 12B to provide electrical coupling therebetween.

In one or more embodiments, the semiconductor die 14 is arranged at a die mounting portion 140 of the surface of the die pad 12A. A rough surface finishing 200 may be formed at a portion of the surface of the die pad 12A neighboring the die mounting portion 140 of the surface of the die pad 12A.

As discussed earlier, the roughened surface finishing 200 may be formed with an arithmetic roughness (as measured via optical measurement, for instance) between 250 nm and 500 nm, preferably between 350 nm and 500 nm may be formed.

Without prejudice to the underlying principles, the details and the embodiments may vary, even significantly, with respect to what has been described by way of example only without departing from the scope of the embodiments.

The claims are an integral part of the technical teaching provided in respect of the embodiments.

The extent of protection is determined by the annexed claims.

1. A method, comprising:
forming a roughened surface finishing at selected portions of a surface of a substrate, wherein the substrate comprises a die pad and an array of electrically conductive leads around the die pad;
arranging a semiconductor die onto the die pad at said surface of the substrate having the roughened surface finishing formed at selected portions of the surface thereof; and
molding an electrically insulating encapsulation onto the semiconductor die arranged onto the die pad, wherein the electrically insulating encapsulation contacts the roughened surface finishing formed at selected portions of said surface of the substrate, wherein the roughened surface finishing counters delamination of the electrically insulating encapsulation from the surface of the substrate;
wherein forming the roughened surface finishing at selected portions of the surface of the substrate comprises:
forming an adhesion promoter finishing layer over the surface of the substrate, and
applying laser beam energy to said selected portions of the surface of the substrate to form a roughened surface at said selected portions of the surface of the substrate.

2. The method of claim 1, wherein the adhesion promoter finishing layer is applied over the roughened surface of the substrate.

3. The method of claim 1, wherein the laser beam energy is applied to the adhesion promoter finishing layer at the surface of the substrate.

4. The method of claim 1, wherein the electrically conductive leads in the array of electrically conductive leads comprise a proximal lead portion and a distal lead portion, and wherein the selected portions of the surface of the substrate where the roughened surface finishing is formed is at the distal lead portion of the electrically conductive leads in the array of electrically conductive leads.

5. The method of claim 4, further comprising providing electrically conductive formations from the semiconductor die arranged at the surface of the die pad and the proximal lead portion of selected leads in the array of electrically conductive leads.

6. The method of claim 1, wherein the die pad comprises a die mounting portion of the surface of the die pad and a neighboring portion, and wherein the selected portions of the surface of the substrate where the roughened surface finishing is formed is at the neighboring portion of the die pad.

7. The method of claim 6, wherein arranging the semiconductor die comprises mounting the semiconductor die at said die mounting portion of the surface of the die pad.

8. The method of claim 1, wherein forming an adhesion promoter finishing layer at the surface of the substrate comprises forming a non-etching adhesion promoter (NEAP) layer at the surface of the substrate.

9. The method of claim 1, wherein the roughened surface finishing formed at the selected portions of the surface of the substrate has an arithmetic roughness between 250 nm and 500 nm.

10. A device, comprising:
a substrate comprising a die pad and an array of electrically conductive leads around the die pad, wherein selected portions of a surface of a substrate have a roughened surface finishing;
a semiconductor die arranged onto the die pad at said surface of the substrate having the roughened surface finishing formed at selected portions of the surface thereof; and
an electrically insulating encapsulation molded onto the semiconductor die arranged onto the die pad, wherein the electrically insulating encapsulation contacts the roughened surface finishing formed at selected portions of said surface of the substrate, wherein the roughened surface finishing counters delamination of the electrically insulating encapsulation from the surface of the substrate;
wherein the roughened surface finishing comprises:
an adhesion promoter finishing layer over the surface of the substrate; and
selected portions of the surface of the substrate having a laser-roughened surface.

11. The device of claim 10, wherein the electrically conductive leads in the array of electrically conductive leads comprise a proximal lead portion and a distal lead portion, and wherein the roughened surface finishing is formed at the distal portion of the electrically conductive leads in the array of electrically conductive leads.

12. The device of claim 11, further comprising electrically conductive formations between the semiconductor die arranged at the surface of the die pad and the proximal lead portion of selected leads in the array of electrically conductive leads to provide electrical coupling therebetween.

13. The device of claim 10, wherein the die pad includes a portion of the surface of the die pad neighboring a die mounting portion of the surface of the die pad, and wherein the roughened surface finishing is formed at the portion of the surface of the die pad neighboring the die mounting portion.

14. The device of claim 10, wherein the adhesion promoter finishing layer is a non-etching adhesion promoter (NEAP) layer.

15. The device of claim 10, wherein the roughened surface finishing formed at the selected locations of the surface of the substrate has an arithmetic roughness between 250 nm and 500 nm, preferably between 350 nm and 500 nm.
